(19) United States
(12) Patent Application Publication
(10) Pub. No.: US 2025/0123324 A1
(43) Pub. Date: Apr. 17, 2025

(54) DEVICE AND METHOD FOR CONTROLLING AIR PURGE EQUIPMENT

(71) Applicant: SILICONWARE PRECISION INDUSTRIES CO., LTD., Taichung City (TW)

(72) Inventor: Cheng-Shao CHEN, Taichung City (TW)

(73) Assignee: SILICONWARE PRECISION INDUSTRIES CO., LTD., Taichung City (TW)

(21) Appl. No.: 18/732,113

(22) Filed: Jun. 3, 2024

(30) Foreign Application Priority Data
Oct. 16, 2023 (TW) 112139426

(51) Int. Cl. G01R 31/28

(52) U.S. Cl. CPC G01R 31/2881; G01R 31/2879

(57) ABSTRACT

A device and method for controlling air purge equipment are provided, which are applicable to controlling an air purge equipment of a testing system. The testing system tests an object to verify the quality thereof. The air purge equipment reduces the internal humidity of the testing system. The device and method for controlling air purge equipment sense a base temperature of the testing system, and sense whether there is a testing element for testing the object in the testing system, and then automatically turn on or turn off the air purge equipment according to the base temperature and the presence of the testing element, so as to avoid that the low temperature causes the moisture to condense into water and consequently affects the testing of the object, and so as to eliminate unnecessary activation of the air purge equipment to avoid accumulating particles or blowing off the object.

### BACKGROUND

### 1. Technical Field

The present disclosure relates to a device and method for controlling air purge equipment, and more particularly, to a device and method for controlling an air purge equipment of a testing system.

### 2. Description of Related Art

Generally, semiconductors must go through a testing step to ensure their quality after being manufactured, and the testing step is usually accomplished by using a testing system 16, as shown in FIG. 1. The testing system 16 comprises a prober 10, a tester 11 and a probe card 12. The tester 11 is configured to receive the probe card 12, and to transmit the testing signal to a wafer 15 under test placed on an adsorption chuck 14 via the probe card 12 and a probe 13, and then to receive the feedback signal of the wafer 15 via the probe card 12 and the probe 13.

With the requirements for automation in the machinery industry and the improvement of the precision requirements, the accuracy of electromechanical integration will be an important key factor, wherein the temperature is an important factor affecting the precision control. The prober may generate moisture when performing low temperature tests, and the surface temperature of the probe card may be lower than the dew point temperature, causing the moisture to condense into water and cause electrical abnormalities. In order to maintain the stable operation of the testing system 16, an air purge equipment can be provided between the tester 11 and the prober 10 to reduce the humidity during the operation. On the other hand, when there is no probe card 12 in the prober 10, there is no need to turn on the air purge equipment even if the humidity standard has been reached; and the air purge equipment even has to be turned off to prevent gas from blowing into the prober (so as to avoid the generation of negative pressure and the accumulation of particles), and to prevent the wafer from being blown off and scratched or fragmented during loading or unloading process.

The conventional air purge equipment of the testing system 16 is turned on or turned off manually and has not reached automation, so the testing steps of semiconductor elements are easily affected due to human errors.

### SUMMARY

In order to address the aforementioned problems, the present disclosure provides a device for controlling air purge equipment, which is applicable to controlling an air purge equipment of a testing system, wherein the testing system is configured for testing an object under test to verify quality of the object under test, and the air purge equipment is configured for reducing internal humidity of the testing system. The device for controlling air purge equipment of the present disclosure comprises: a temperature sensor configured for sensing a base temperature of the testing system; a testing element sensor configured for sensing whether there is a testing element for testing the object under test in the testing system; and an air purge controller configured for turning on or turning off the air purge equipment according to the base temperature and presence of the testing element in the testing system.

The present disclosure further provides a method for controlling air purge equipment, which is applicable to controlling an air purge equipment of a testing system. The method for controlling air purge equipment of the present disclosure comprises: sensing a base temperature of the testing system; sensing whether there is a testing element for testing the object under test in the testing system; and determining to turn on or turn off the air purge equipment according to the base temperature and presence of the testing element in the testing system.

The present disclosure automatically turns on or turns off the air purge equipment of the testing system according to the temperature of the testing system and the presence of the testing element, so as to prevent moisture from condensing into water due to low temperature and affecting the testing of the object under test. The present disclosure can also eliminate unnecessary activation of the air purge equipment, thereby preventing gas from blowing into the testing system (thus avoiding particle accumulation) or preventing the object under test from being blown off and damaged during loading or unloading process.

### BRIEF DESCRIPTION OF THE DRAWINGS

FIG. 1 is a schematic view showing a conventional testing system.

FIG. 2 is a block diagram showing a device for controlling air purge equipment of the present disclosure.

FIG. 3 is a flowchart illustrating a method for controlling air purge equipment of the present disclosure.

### DETAILED DESCRIPTION

The following describes the implementation of the present disclosure with examples. Those skilled in the art can easily understand other advantages and effects of the present disclosure from the contents disclosed in this specification.

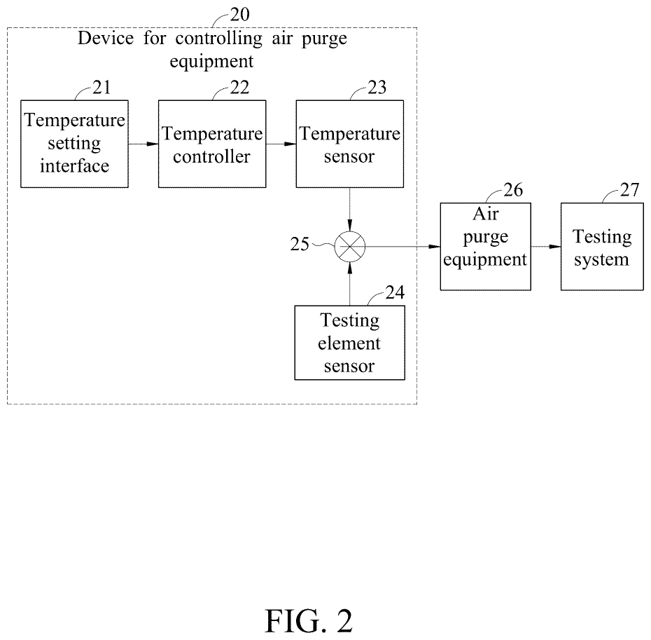

FIG. 2 is a block diagram showing a device 20 for controlling air purge equipment of the present disclosure. The device 20 for controlling air purge equipment comprises a temperature setting interface 21, a temperature controller 22, a temperature sensor 23, a testing element sensor 24 and an air purge controller 25. The temperature setting interface 21 is electrically connected to the temperature controller 22, the temperature controller 22 is electrically connected to the temperature sensor 23, and the air purge controller 25 is electrically connected to the temperature sensor 23, the testing element sensor 24 and an air purge equipment 26.

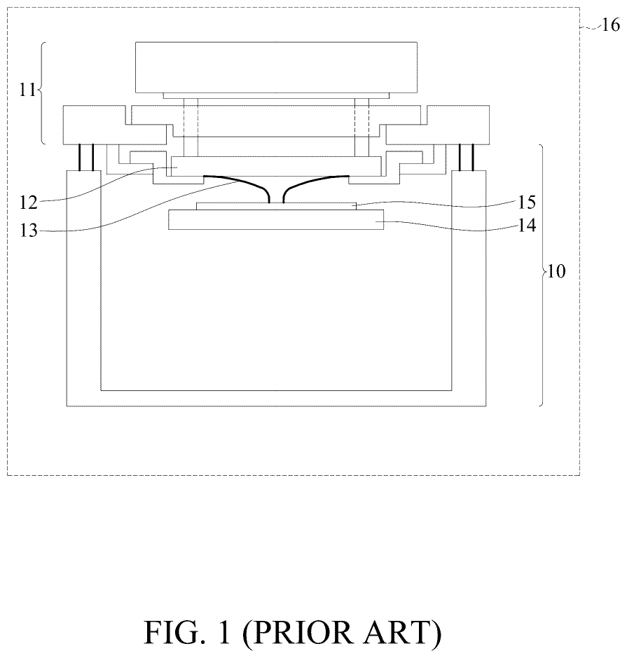

The device 20 for controlling air purge equipment is applicable to controlling the air purge equipment 26 of a testing system 27, such as turning on or turning off the air purge equipment 26. The testing system 27 can be the testing system 16 shown in FIG. 1 or other semiconductor element testing systems, and the testing system 27 is configured for testing an object under test placed in the testing system 27 to verify the quality of the object under test. The object under test can be a semiconductor element, such as a wafer, a package, or an electrical element. The air purge equipment 26 is configured for reducing the internal humidity of the testing system 27 to prevent moisture from condensing into water due to low temperature and affecting the testing of the object under test.

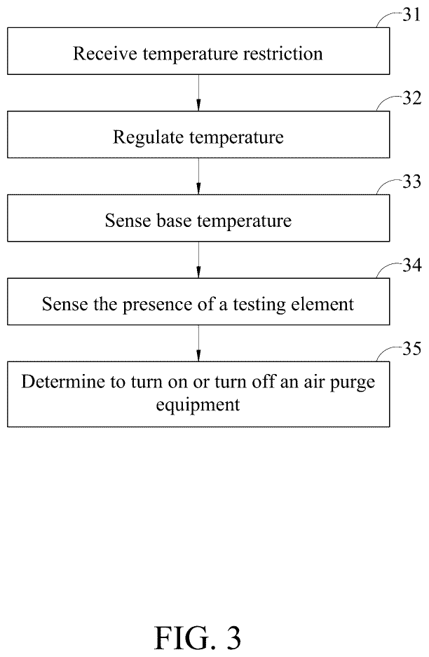

Please refer to FIG. 3 at the same time. FIG. 3 is a flowchart illustrating a method for controlling air purge equipment of the present disclosure, and the method can be performed by the device 20 for controlling air purge equipment. The following describes the steps of the method shown in FIG. 3.

First, in step 31, the temperature setting interface 21 receives the temperature restriction set by a user. For instance, the temperature setting interface 21 may comprise input devices such as buttons or keys, or may comprise a remote control signal receiver to receive the temperature restriction set by the user.

In step 32, the temperature controller 22 regulates the temperature of a space where the testing system 27 is located according to the temperature restriction. For instance, the temperature restriction can be a target temperature, and the temperature controller 22 can control the air conditioning equipment (not shown) in the space, such that the temperature of the space approaches the target temperature.

In step 33, the temperature sensor 23 senses a base temperature of the testing system 27. The base temperature is the surface temperature or the internal temperature of the testing system 27.

In step 34, the testing element sensor 24 senses whether there is a testing element in the testing system 27. The testing element is configured for testing the aforementioned object under test. In specific, the testing element is configured to input a testing signal into an electrical testing point (e.g., a bonding pad or an electrode) of the object under test, and to receive a feedback signal generated by the object under test from the electrical testing point after the testing signal is received by the object under test. The testing element can be the probe card 12 shown in FIG. 1 or other electronic elements with the same function. The testing element sensor 24 can convert the existing information of the testing element into an electrical signal, and the testing element sensor 24 can read the electrical signal to determine whether the testing element exists in the testing system 27.

In step 35, the air purge controller 25 determines to turn on or turn off the air purge equipment 26 according to the base temperature and whether the testing element exists in the testing system 27. In specific, if the base temperature is lower than or equal to a first critical temperature, and the testing element exists in the testing system 27, then the air purge controller 25 turns on the air purge equipment 26 to reduce the internal humidity of the testing system 27. If the base temperature is higher than a second critical temperature, or the testing element does not exist in the testing system 27, then the air purge controller 25 turns off the air purge equipment 26. The second critical temperature is higher than or equal to the first critical temperature.

In an embodiment, the air purge controller 25 can be a logic circuit, a control circuit, a micro-controller unit (MCU), an embedded controller, or a processor.

In an embodiment, the first critical temperature and the second critical temperature are all 5° C. Hence, the logical judgment for the air purge controller 25 to determine to turn on or turn off the air purge equipment 26 is as listed in the following table.

| Temperature | Whether the testing | The air purge |
|---|---|---|
| ≤5° C. | element exists | equipment |
| Yes | Yes | Turn on |
| Yes | No | Turn off |
| No | Yes | Turn off |
| No | No | Turn off |

As can be seen from the above table, the air purge controller 25 turns on the air purge equipment 26 only when the base temperature is lower than or equal to 5° C. and the testing element exists in the testing system 27. When the base temperature is higher than 5° C. or the testing element does not exist in the testing system 27, the air purge controller 25 turns off the air purge equipment 26.

In an embodiment, the first critical temperature is 5° C., and the second critical temperature is 7° C. Hence, the air purge controller 25 of the present disclosure turns on the air purge equipment 26 only when the base temperature is lower than or equal to 5° C. and the testing element exists in the testing system 27. When the base temperature is higher than 7° C. or the testing element does not exist in the testing system 27, the air purge controller 25 turns off the air purge equipment 26.

In summary, the present disclosure automatically turns on or turns off the air purge equipment according to the temperature of the testing system and the presence of the testing element, so as to prevent moisture from condensing into water due to low temperature and affecting the testing of the object under test. The present disclosure can also eliminate unnecessary activation of the air purge equipment, thereby preventing gas from blowing into the testing system (thus avoiding particle accumulation) or preventing the object under test from being blown off and damaged during loading or unloading process.

The above embodiments are provided for illustrating the principles of the present disclosure and its technical effect, and should not be construed as to limit the present disclosure in any way. The above embodiments can be modified by one of ordinary skill in the art without departing from the spirit and scope of the present disclosure. Therefore, the scope claimed of the present disclosure should be defined by the following claims.

What is claimed is:

1. A device for controlling an air purge equipment, which is applicable to controlling the air purge equipment configured for reducing internal humidity of a testing system which is configured for testing an object under test to verify quality of the object under test, the device for controlling air purge equipment comprising:
a temperature sensor configured for sensing a base temperature of the testing system;
a testing element sensor configured for sensing whether there is a testing element for testing the object under test in the testing system; and
an air purge controller configured for turning on or turning off the air purge equipment according to the base temperature and presence of the testing element in the testing system.

2. The device for controlling air purge equipment of claim 1, wherein the testing element is configured to input a testing signal into an electrical testing point of the object under test, and to receive a feedback signal generated by the object under test from the electrical testing point after the testing signal is received by the object under test.

3. The device for controlling air purge equipment of claim 1, wherein the base temperature is a surface temperature or an internal temperature of the testing system.

4. The device for controlling air purge equipment of claim 1, wherein if the base temperature is lower than or equal to a first critical temperature, and the testing element exists in the testing system, then the air purge controller turns on the air purge equipment.

5. The device for controlling air purge equipment of claim 4, wherein if the base temperature is higher than a second critical temperature, or the testing element does not exist in the testing system, then the air purge controller turns off the air purge equipment.

6. The device for controlling air purge equipment of claim 5, wherein the second critical temperature is higher than or equal to the first critical temperature.

7. The device for controlling air purge equipment of claim 5, wherein the first critical temperature is 5° C., and the second critical temperature is 5° C. or 7° C.

8. The device for controlling air purge equipment of claim 1, further comprising:
a temperature setting interface configured to receive temperature restriction set by a user; and
a temperature controller configured to regulate a temperature of a space where the testing system is located according to the temperature restriction.

9. A method for controlling air purge equipment, which is applicable to controlling an air purge equipment configured for reducing internal humidity of a testing system which is configured for testing an object under test to verify quality of the object under test, the method for controlling air purge equipment comprising:
sensing a base temperature of the testing system;
sensing whether there is a testing element for testing the object under test in the testing system; and
determining to turn on or turn off the air purge equipment according to the base temperature and presence of the testing element in the testing system.

10. The method for controlling air purge equipment of claim 9, wherein the testing element is configured to input a testing signal into an electrical testing point of the object under test, and to receive a feedback signal generated by the object under test from the electrical testing point after the testing signal is received by the object under test.

11. The method for controlling air purge equipment of claim 9, wherein the base temperature is a surface temperature or an internal temperature of the testing system.

12. The method for controlling air purge equipment of claim 9, further comprising:
if the base temperature is lower than or equal to a first critical temperature, and the testing element exists in the testing system, then turning on the air purge equipment.

13. The method for controlling air purge equipment of claim 12, further comprising:
if the base temperature is higher than a second critical temperature, or the testing element does not exist in the testing system, then turning off the air purge equipment.

14. The method for controlling air purge equipment of claim 13, wherein the second critical temperature is higher than or equal to the first critical temperature.

15. The method for controlling air purge equipment of claim 13, wherein the first critical temperature is 5° C., and the second critical temperature is 5° C. or 7° C.

16. The method for controlling air purge equipment of claim 9, further comprising:
receiving temperature restriction set by a user; and
regulating a temperature of a space where the testing system is located according to the temperature restriction.
